(19) United States
(12) Patent Application Publication
(10) Pub. No.: US 2019/0157012 A1
(43) Pub. Date: May 23, 2019

(54) COMPOSITIONS AND METHODS FOR POLARIZATION-SWITCHED, SOLID-STATE MOLECULAR PUMPING

(71) Applicant: BATTELLE MEMORIAL INSTITUTE, Richland, WA (US)

(72) Inventors: Carlos A. Fernandez, Kennewick, WA (US); Evgueni Polikarpov, Richland, WA (US); Abhijeet J. Karkamkar, Richland, WA (US); Gregory W. Coffey, Richland, WA (US); Satish K. Nune, Richland, WA (US); Phillip K. Koech, Richland, WA (US); Bernard P. McGrail, Pasco, WA (US); John A. Roberts, Pasco, WA (US)

(73) Assignee: BATTELLE MEMORIAL INSTITUTE, Richland, WA (US)

(21) Appl. No.: 16/177,647

(22) Filed: Nov. 1, 2018

Related U.S. Application Data
(60) Provisional application No. 62/581,327, filed on Nov. 3, 2017.

(51) Int. Cl. H01G 9/022; H01G 9/042; H01G 9/20; H05K 7/20; G02F 1/1523; G02F 1/155; G02F 1/163

(52) U.S. Cl. CPC H01G 9/022; H01G 9/042; H01G 9/2031; G02F 2001/1517; G02F 1/1525; G02F 1/155; G02F 1/163; H05K 7/20363

(57) ABSTRACT

Disclosed are methods and compositions for alternatingly adsorbing and desorbing sorbate molecules by changing the adsorption affinity of polarizable molecular sorbent molecules attached to surfaces of conductors, attached to dielectric materials between the conductors, or attached to both. The conductors and optionally a dielectric material can be arranged as a capacitor.

### CROSS-REFERENCE TO RELATED APPLICATIONS

This invention claims priority from U.S. provisional patent application No. 62/581,327, entitled System and Methods for Polarization-Switched, Solid-State Molecular Pumping, filed Nov. 3, 2017. The application is incorporated herein by reference.

### ACKNOWLEDGEMENT OF GOVERNMENT SUPPORT

This invention was made with Government support under Contract DE-AC0576RL01830 awarded by the U.S. Department of Energy. The Government has certain rights in the invention.

### FIELD

The present disclosure relates generally to methods, compositions, and systems for non-mechanical pumping and/or pumping fluids with few or no moving parts. More particularly it relates to polarization-switched, solid-state, molecular pumping.

### BACKGROUND

Although methods and systems vary, the most traditional way of pumping fluids against pressure gradients is by means of mechanical compressors. Such compressors operate with the same basic underlying principles and achieve compression by changing the velocity, enclosed volume, density, and/or temperature of the gas flowing through the compressor. These traditional methods and systems utilize moving parts that require frequent maintenance and that introduce inefficiencies related to mechanical compressors, including those due to energy conversions (combustion to mechanical rotation) and associated friction and dissipation (heat transfer). Accordingly, a need for efficient pumping methods, compositions, and systems exists.

### SUMMARY

Disclosed are methods and compositions for pumping fluids by alternating or cycling the adsorption affinity of a polarizable molecule for a sorbate. In some embodiments, a method comprises the steps of alternating a polarization-switched, solid-state, molecular (POSSM) pump between a first condition and a second condition. The POSSM pump can comprise a pair of electrically connected electrodes, at least one of which has surfaces on which polarizable molecules are attached, or having between the electrodes a dielectric material with the polarizable molecules attached to surfaces thereof, or having both. In the first condition, a non-zero electric potential difference is applied between the conductors and in the second condition, a lower electric potential difference is applied relative to the first condition. The method can further comprise adsorbing sorbate molecules from a fluid to the polarizable molecules in the first or second condition and desorbing the sorbate molecules from the polarizable molecules in the second or first condition, respectively.

In certain embodiments, the polarizable molecules can be considered sorbent molecules. They can comprise non-centrosymmetric molecules. Alternatively, or in addition, the polarizable molecules can be conjugated molecules. The polarizable molecules can comprise molecules having a donor and an acceptor group. The polarizable sorbent molecules can comprise available hydrogen for hydrogen bonding with the sorbate molecules. In certain embodiments, the polarizable molecules can comprise chromophores. Examples of polarizable molecules can include, but are not limited to 4-acetamidothiophenols, quinoxalines, pyridines, pyrimidines, pyrrole, tetracyanoquinodimethane, donor substituted tetracyanoquinodimethanes, quinones, thiophenes, benzothiophenes, or combinations thereof. An example of a donor substituted tetracyanoquinodimethane includes pyridine substituted tetracyanoquinodimethane

In certain embodiments, the method can further comprise reversibly changing an adsorption enthalpy value of the polarizable molecule in the presence of the sorbate molecule when switching between the first and second conditions.

In certain embodiments, the method further comprises alternating the sorbate molecule's polarization state in the first and second conditions. Sorbate molecules can be polarizable molecules, can have a dipole, can have a charge (i.e., be a charged molecule, or ion), can have available hydrogen for H-bonding with the polarizable sorbent molecules, or combinations thereof. In other words, in addition to the polarizable sorbent molecules, the sorbate molecules can have a polarization change. Alternatively, or in addition, the sorbate molecules can interact strongly with the polarizable sorbent molecules in the first or second condition via H-bonding or different types of electrostatic and/or van der Waals interactions.

In certain embodiments, the sorbate molecules are not charged molecules or particles. As described elsewhere herein, the inventors have determined that various aspects of POSSM pumping facilitate non-mechanical pumping of molecules that are not necessarily charged or are not necessarily part of a liquid comprising an electrolyte.

The sorbate molecules can comprise a liquid, a gas, or combination of both. In other words, a fluid that is a liquid, a gas, or a combination of both can comprise the sorbate molecules. In certain embodiments, the sorbate molecules comprise refrigerant molecules. Examples of refrigerant molecules include, but are not limited to fluorocarbons, chlorofluorocarbons, hydrochlorofluorocarbons, and hydrofluorocarbons (HFC) such as 1-hydropentadecafluoroheptane, R23, R32, R134a, R404A, R407A, R407C, R407F, R410A, R417A, R422A, R422D, R423A, R424A, R427A, R428A, R434A, R437A, R438A, R442A, R449A, R507A, R508B, ISCEON MO89, and R1234yf.

In certain embodiments, the sorbate molecules can comprise compounds relevant to catalysis, separations, pumping, or sensing applications. Examples of sorbate molecules can comprise, but are not limited to CO₂, Ar, Xe, Kr, Rn, NH₃, O₂, N₂, Cl₂, Br₂, I₂, carbon monoxide (CO), hydrogen chloride (HCl), nitrous oxide (N₂O), nitrogen trifluoride (NF₃), sulfur dioxide (SO₂), sulfur hexafluoride (SF₆), hydrocarbon gases (e.g., alkanes, alkenes, alkynes), volatile organic compounds (e.g. formaldehyde, d-Limonene, toluene, acetone, ethanol, 2-propanol, hexanal), pesticides (e.g., DDT, chlordane), plasticizers (e.g., phthalates), fire retardants (e.g., PCBs, PBB), or combinations thereof. In embodiments wherein the sorbate is catalyzed by the sorbent, the conductive material, the dielectric material, or combinations thereof, examples of sorbate molecules can include, but are not limited to, propylene (i.e., catalyzed polymerization to polypropylene), petroleum components (i.e., catalyzed desulfurization of hydrocarbons), ethene (i.e., catalyzed oxidation to ethylene oxide), water and methane (i.e., catalyzed hydrogen production by steam reforming), or combinations thereof.

In certain embodiments, the dielectric material comprises a porous material. Examples of dielectric materials, porous or non-porous, can include, but are not limited to, ceramic materials (such as titanium dioxide, alumina, calcium titanate, glass ceramic, zirconia, aluminum nitride), celluloid, cellulose acetate, epoxy resin, glass, polystyrene, polyimide, plexiglass, paper, Teflon, neoprene, air, Daramic® (a silica filled polyethylene material used often as a membrane), or combinations thereof. Alternatively, or in addition, one or more of the electrodes can comprise a porous material. In certain embodiments, the dielectric material, one or more of the electrodes, or a combination thereof comprises a catalyst material the further comprising the step of catalyzing a reaction involving the sorbate via the catalyst material. Examples of catalyst materials can include, but are not limited to, vanadium oxides, iron oxides in alumina, platinum-rhodium, Mo—Co, and similar bimetallic alloys, nickel and nickel-containing catalysts, silver or gold on alumina, NiO—TiO₂/WO₃, TiCl₃ on MgCl₂, or combinations thereof.

In certain embodiments, the POSSM pump further comprises a plurality of pairs of electrically connected electrodes. The plurality of pairs of electrically connected electrodes can be arranged along a sorbate-propagation path and the method can further comprise the step of selectively switching the pairs of electrodes between the first and second conditions in a coordinated manner, thereby causing flow of the sorbate molecules. The plurality of pairs of electrically connected electrodes can be arranged in an interleaved configuration.

In some embodiments, the composition can comprise a sorbent material attached to surfaces of a conductor, attached to surfaces of a dielectric material adjacent to the conductor, or attached to both, the sorbent material comprising polarizable molecules, wherein the polarizable molecules change polarization state in response to an applied electric field and wherein an adsorption affinity of the polarizable molecules for a sorbate also changes in response to the electric field.

In certain embodiments, the polarizable molecules comprise 4-acetamidothiophenols, quinoxalines, pyridines, pyrimidines, pyrrole, tetracyanoquinodimethane, donor substituted tetracyanoquinodimethanes, quinones, thiophenes, benzothiophenes, or combinations thereof.

In certain embodiments, the sorbate comprises refrigerant compounds. Examples of refrigerant compounds can include, but are not limited to, HFCs such as 1-hydropentadecafluoroheptane, R23, R32, R134a, R404A, R407A, R407C, R407F, R410A, R417A, R422A, R422D, R423A, R424A, R427A, R428A, R434A, R437A, R438A, R442A, R449A, R507A, R508B, ISCEON MO89, and R1234yf. In certain embodiments, an adsorption-desorption enthalpy change of the polarizable molecules and the sorbate molecules have a non-zero value. In certain embodiments, the conductor, the dielectric material, or both comprise a catalyst that catalyzes reactions involving the sorbate. In certain embodiments, the sorbate molecules are not charged molecules or particles. In certain embodiments, the sorbate molecules comprise polarizable molecules, hydrogen bond donors, hydrogen bond acceptors, charged molecules, polar molecules, or a combination thereof.

The purpose of the foregoing summary and the latter abstract is to enable the United States Patent and Trademark Office and the public generally, especially the scientists, engineers, and practitioners in the art who are not familiar with patent or legal terms or phraseology, to determine quickly from a cursory inspection the nature and essence of the technical disclosure of the application. Neither the summary nor the abstract is intended to define the invention of the application, which is measured by the claims, nor is it intended to be limiting as to the scope of the claims in any way.

### BRIEF DESCRIPTION OF THE DRAWINGS

FIG. 1 is an illustration of one embodiment of a polarizable molecule, a 4-acetamidothiophenol chromophore.

FIG. 2 is a schematic diagram depicting an embodiment of a portion of a POSSM pump alternating between two conditions.

FIGS. 3A-3D include scanning electron micrographs of A) backscattered electrons (BE) image of Au (light) on C fabric (darker); B) secondary electrons (SE) image of Au globules on C fiber; C) BE image of Au globules encrusting the cut ends of the C fabric; D) SE image of Au on C fabric.

FIGS. 4A and 4B include calorimetric results for sorbate adsorption and desorption on a double layer capacitor upon switching “on” and switching “off” an electric field, respectively. The sorbate is a refrigerant molecule.

FIG. 5 compares images that illustrate the effect of functionalization of the ITO/ZrO₂ electrode with the organic chromophore on the capacitor dielectric breakdown voltage.

FIG. 6 is a schematic of an embodiment of a capacitor cell. The cell was used in the electrically-switched sorption/desorption experiments.

FIG. 7 includes residual gas analysis (RGA) results indicating the response of the capacitor cell to switching off of the capacitor voltage and the resulting release of sorbate (e.g., refrigerant). RGA mass signals of the two characteristic fragments of the HFC, 45 and 65 a.m.u. are shown.

FIGS. 8A and 8B include schematics of embodiments of a POSSM pump having a plurality of pairs of electrically connected electrodes.

### DETAILED DESCRIPTION

Disclosed are methods, compositions, and systems for pumping fluids by alternating or cycling the adsorption affinity of polarizable sorbent molecules attached to a surface of an electrode in a pair of electrodes, a surface of a dielectric material between the pair of electrodes, or surfaces of both. According to one perspective, compression operates at the molecular level and involves zero moving parts. The methods, compositions, and systems can be applicable in various applications including, but not limited to, pumping, catalysis, separations, and chemical sensing. Accordingly, in some embodiments, pumping can refer to moving a fluid toward a catalyst or a membrane for separation. Examples of applications include heating, ventilation, air-conditioning (HVAC) systems.

Embodiments described herein can eliminate mechanical compressor inefficiencies due to energy conversions (e.g., combustion to mechanical motion) and associated friction and dissipation (e.g., heat transfer). Furthermore, they can address the need for energy-efficient means for the transport of fluids against gradients. The required energy input is associated with alternating the potential applied across the layer of sorbent molecules and requires no moving parts.

Embodiments described herein differ from other techniques affecting a material's affinity for chemicals or pore sizes under the influence of variations in pressure, temperature, pH, or electrical potential. Capillary electrophoresis, employed mainly in separation applications uses electrical potential to separate ions from neutral molecules based on ionic mobility. Similarly, electroosmotic pumps can only operate with conducting (ionic or polar) liquids. Flow and pressure are a result of ion drag forces generated by mobile ions of electric double layers (EDL), which form at the solid-liquid interface. Nonpolar liquids are usually nonconducting and cannot be pumped using traditional electroosmotic pumps. There can also be electrical bias effects on pore formation in materials such as semiconductors. The inventors have determined that embodiments described herein are not limited to charged particles and molecules or to conducting liquid media, but are also effective with neutral molecules and weakly electronegative or electropositive molecules. In contrast, capillary electrophoresis and/or electroosmotic flow is inefficient or incapable when operating on neutral molecules. Furthermore, embodiments described herein do not require an electrolyte or electrical conductivity, so it can be applied to pump, in principle, any liquid or gaseous fluid.

Embodiments described herein encompass a compression approach that operates at the molecular level and can involve zero moving parts for compression and expansion of fluids. Certain embodiments include polarizable molecules similar to those used for nonlinear optics (NLO) and porous sorbent materials, (e.g. porous metal oxides, zeolites) for gas uptake. Application of an electric field can stimulate charge separation from donor(+) to acceptor(−), changing the material's affinity for sorbates. Examples can include, but are not limited to, refrigerants such as carbon dioxide, ammonia, and hydrofluorocarbons (HFCs), including 2,3,3,3-tetrafluoropropene (1234yf) slated to replace R134a in vehicles in the EU. Changes in electric polarization by an applied potential can activate/deactivate refrigerant binding at the electrodes on which polarizable sorbent molecules are attached. Cycling delivers energy in the form of the difference between the charging and discharging voltages, times the amount of charge passed. Since polarization does not involve the passage of current between the active material and the capacitor poles, the migration of counterions (as in an electrochemical device) is not required. Also, for a capacitor, no 1:1 correspondence between charges passed and molecules adsorbed is required.

Functionalization of electrodes in a capacitor with polarizable molecules attached are described. The application of an electric field to a double-layer capacitor where at least one of the electrodes is coated with the polarizable molecules showed that a higher applied voltage is required for a breakdown of the capacitor dielectric as compared to the same capacitor without the polarizable molecules attached. One reason for this difference is the local electric field in the opposite direction of the applied external potential, generated by the polarizable molecules on the surface. This electric field should be associated to the polarization/charge redistribution in the polarizable molecules.

The non-mechanical molecular pumping described herein has potential to address the need for new energy-efficient methods for the transport of fluids against pressure gradients. Since the concept can be used, in principle, to transport any fluid (e.g., ionic, polar, non-polar), it could be exploited for refrigeration, catalysis, gas separation, and sensing among many other potential applications.

In one embodiment, switching “on” and “off” a capacitor results in non-mechanical pumping. In the “on” position, polarizable molecules within the capacitor cavity can generate temporary dipoles in response to the applied electric field attracting and concentrating sorbate molecules (e.g., refrigerant molecules via hydrogen bonding). When the capacitor is switched off, the polarization disappears together with the H-bonding interaction, and the refrigerant molecules are set free.

Embodiments described herein encompass polarization-switched solid-state molecular (POSSM) pumps for automobile A/C systems. POSSM can eliminate the related mechanical compressor inefficiencies due to energy conversions (combustion to mechanical rotation) and associated friction and dissipation (heat transfer). Instead, POSSM can operate by rapidly cycling the adsorption affinity of a thin layer of polarizable molecular sorbent arranged in a capacitor with volumetric pumping rates useful in traditional A/C and refrigeration/freezing systems while consuming one-third the energy. Embodiments also include other important refrigerants, such as CO₂ (currently gaining market share for commercial refrigeration) and NH₃ (widely used for industrial cooling units). Disclosed herein are durable, energy-efficient compressors for heat pump systems, a potentially disruptive innovation in a massive and diverse end-use energy market.

Some embodiments use voltage to control HFC adsorption and desorption in a porous material (high surface area) with donor and acceptor molecules embedded in their pores and oriented within a capacitor cavity. Changing the applied voltage will redistribute the electron density within the chromophores and change their affinity for a specific sorbate, providing a physical basis for non-mechanical pumping. One interaction that can be exploited is hydrogen bonding with the acceptor group of the polarized organic molecule interacting with the hydrogen of the HFC. For example, the enthalpy of hydrogen bonding between 1-hydropentadecafluoroheptane [CHF₂(CF₂)₅CF₃] and the strong base triethylamine has been measured at 5 kcal mol⁻¹, suggesting that sufficient binding strength can be achieved with a suitable choice of polarizable organic molecules. The response to the presence of an electric field in organic materials arises from charge transfer from the donor to the acceptor. Since polarization does not involve the passage of current between the active material and the capacitor poles, the migration of counterions (as in electrochemical devices) is not required. Cycling delivers energy in the form of the difference between the charging and discharging voltages, times the amount of charge passed.

Some aspects of the polarization effect are described herein, where analysis of contact angle as a function of an applied potential to a double layer capacitor where polarizable sorbent molecules were introduced into the capacitor structure. The presence of an electric field generated by the (external) potential-induced polarization of the sorbent molecules in the capacitor is demonstrated. Certain embodiments include a capacitor where the ability to pump sorbate molecules resides in switching on and off the polarization of sorbent molecules inside the capacitor which in turn concentrate and release the sorbate molecules providing the physical basis for molecular pumping. In certain embodiments, the change in dipole moment from zero (or nearly zero) to a larger magnitude can generate an interaction between the polarizable sorbent molecules inside the capacitor and the sorbate molecules via hydrogen bonding, electrostatic interaction, and/or van der Waals interactions concentrating the sorbate molecules inside the capacitor. Switching the dipole moment back to zero (or a value lower than the “on” state) will release the sorbate molecules. In certain embodiments, the capacitor's dielectric or electrodes can be a porous material to increase the capacity of the device for sorbate molecules. In certain embodiments, the polarizable sorbent and the porous material don't need to be electrical conductors.

Embodiments are not limited to pumping in HVAC and/or refrigeration systems. Also encompassed is polarization-switched selectivity as a way to bring about selectivity of a sorbent towards a given sorbate and extend interactions between a sorbent and a sorbate beyond simple molecular sieving or chemical affinity. For example, in catalysis, the adsorption strengths and activation energies for reactions of molecules on the surfaces of polarizable materials could be sensitive to the polarization direction. Switching “on” the catalyst can cause it to be selective towards one precursor over another one and/or to selectively produce one product over another one. Polarization-switched selectivity can also be applied in gas separation and sensing where, once again, selectivity can be brought about or further enhanced to target a specific sorbate over others based on switched polarization followed by adsorption. One example could include applications in military and defense by sensing/detection and neutralization of harmful chemicals, such as nerve agents.

In some embodiments, a solid metal catalyst inside a porous support, due to having a hydrophilic nature, can repel organic species or can bind very strongly to polar groups. Polarizable sorbent molecules attached to the porous support can be turned on and off by application of a potential across a capacitor plate structure, which enables weak hydrogen bonding interactions between the reactant and polarizable molecules in the “on” position and disables the hydrogen bonding interaction in the “off” position can thus enable switchable electrocatalysis.

In certain embodiments, electrocatalytic hydrogenation of aromatic aldehyde (benzaldehyde) and ketones (acetophenone) is limited to reduction of carbonyl groups to alcohols (benzyl alcohol) and (phenylethanol) respectively while the aromatic ring doesn't hydrogenate due to preferential orientation of the carbonyl group towards the metal nanoparticles. Addition of polarizable molecules, such as an aromatic non-centrosymmetric molecule, will enable preferential adsorption of the aromatic portion via Pi interactions. This will facilitate electroreduction of the previously inaccessible aromatic component thus reducing benzaldehyde to cyclohexylmethanol and acetophenone to 2 cyclohexylethanol.

The following explanations of terms and abbreviations are provided to better describe the present disclosure and to guide those of ordinary skill in the art in the practice of the present disclosure. As used herein, “comprising” means “including” and the singular forms “a” or “an” or “the” include plural references unless the context clearly dictates otherwise. The term “or” refers to a single element of stated alternative elements or a combination of two or more elements, unless the context clearly indicates otherwise.

Unless explained otherwise, all technical and scientific terms used herein and in the attachments have the same meaning as commonly understood to one of ordinary skill in the art to which this disclosure belongs. Although methods and materials similar or equivalent to those described herein and in the attachments can be used in the practice or testing of the present disclosure, suitable methods and materials are described below and in the attachments. The materials, methods, and examples are illustrative only and not intended to be limiting. Other features of the disclosure are apparent from the following detailed description, the attachments, and the claims.

Unless otherwise indicated, all numbers expressing quantities of components, molecular weights, percentages, temperatures, times, and so forth, as used in the specification, the attachments, or the claims are to be understood as being modified by the term “about.” Accordingly, unless otherwise implicitly or explicitly indicated, or unless the context is properly understood by a person of ordinary skill in the art to have a more definitive construction, the numerical parameters set forth are approximations that may depend on the desired properties sought and/or limits of detection under standard test conditions/methods as known to those of ordinary skill in the art. When directly and explicitly distinguishing embodiments from discussed prior art, the embodiment numbers are not approximates unless the word “about” is recited.

To further illustrate certain embodiments of the disclosed methods, compositions and systems for pumping, and to provide various comparative analyses and data, attached are some examples with comparison test data.

A large fraction of global energy demand derives from vapor compression heat pumps. This demand spans every sector of the economy, from air conditioners in small cars to massive installations serving entire municipal districts with an annual electricity consumption of fifteen percent in the United States.

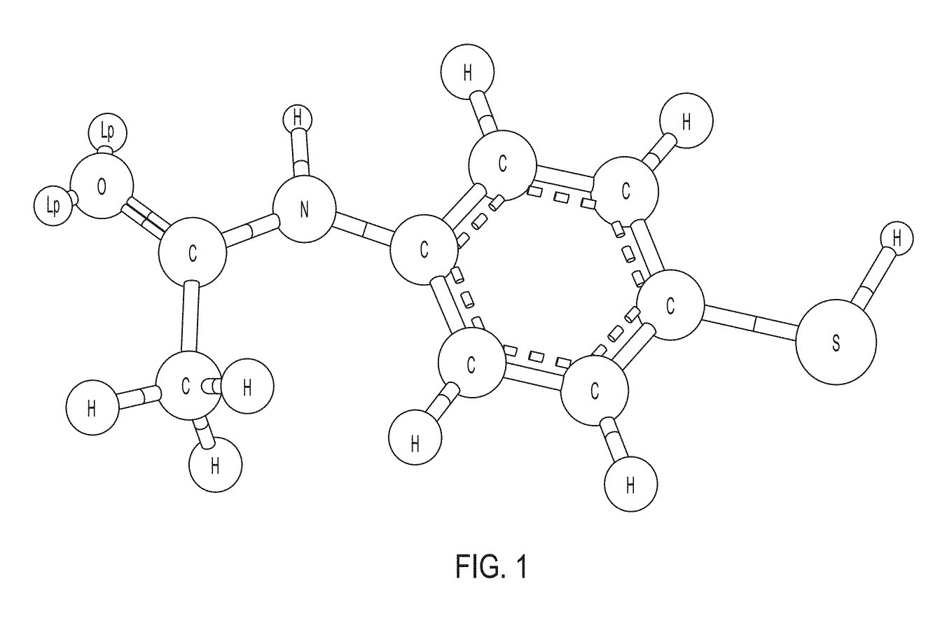

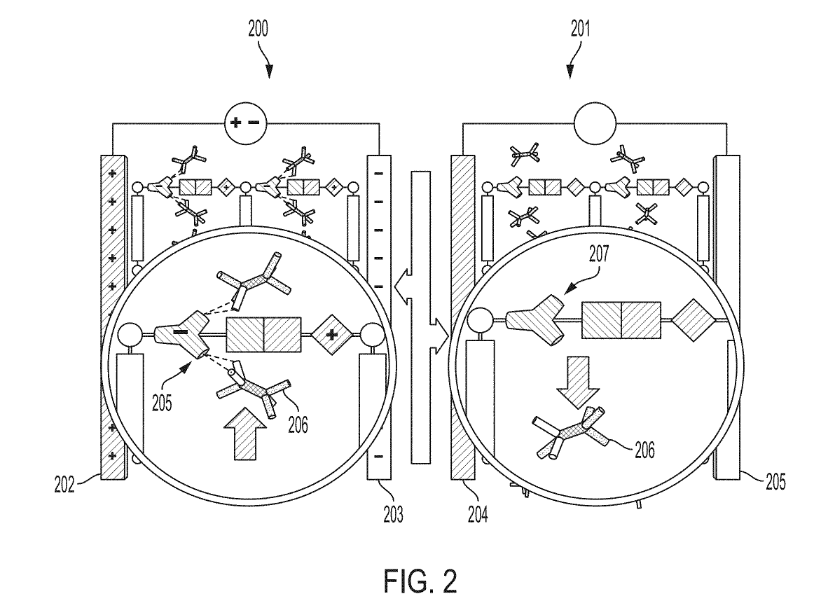

A POSSM pump according to embodiments described herein can comprise a double-layer capacitor enclosed in a gas exchange chamber. The working electrode of the capacitor is a gold-coated porous carbon that hosts a polar chromophore (4-acetamidothiophenol, FIG. 1) as the polarizable sorbent molecule. The working electrode is separated from the counter-electrode (e.g., a steel plate) by a ceramic dielectric. The reversible sorption mechanism can involve 1) polarization of the chromophore under an applied electric field, followed by 2) hydrogen bonding between the chromophore and a hydrofluorocarbon (HFC) as the sorbate molecule. When the capacitor is switched off, the polarization disappears together with the H-bonding interaction, and the HFC molecules are set free. This mechanism is illustrated in FIG. 2 and provides one example of a physical basis for non-mechanical pumping. In a first condition 200 having an applied electric field across electrodes 202 and 203, polarizable molecules 205 can have an increased affinity for a sorbate molecule 206. In a second condition 201, with no (or decreased) electric field across electrodes 204 and 205, the polarizable molecule 207 has a lower affinity for the sorbate 206. Since it is operating at the molecular level, no moving parts are required for compression. Then, the majority of the efficiency gains is expected to be due to elimination of 1) energy conversion losses (combustion to mechanical rotation) and 2) associated friction and dissipation inherent to the pumps with conventional mechanical compressors. A molecular pump can operate by rapidly cycling the adsorption affinity of a thin layer of polarizable molecular sorbent arranged in a capacitor with similar volumetric pumping rates to traditional air conditioning and refrigeration/freezing systems while consuming significantly less energy.

Gold was deposited onto porous carbon substrates by electroplating from a basic solution at room temperature. The purpose of the gold coating was to provide the porous electrode with enhanced binding capabilities by means of covalent Au—S bonds. The amount of gold deposited onto the carbon substrate was measured by ICP-MS. The surface area and pore volume of the substrate before and after gold coating was characterized by using nitrogen adsorption-desorption measurements of carbon sheets, gold-coated carbon sheets, and gold-coated carbon sheets functionalized with 4-acetamidothiophenol. Briefly, a piece of gold sheet (negative electrode) and a porous carbon substrate (positive electrode) were placed in 150 mL of aqueous solution containing 0.9 g of KAu(CN)₂, 4.5 g of KCN, 4.5 g K₂HPO₄ and 4.5 g K₂CO₃ (pH˜11). A voltage between 1 and 2 Volts was applied to the electrodes using a power supply to maintain a current density of 2 mA/cm². The mass of gold deposited on carbon was controlled by varying the duration of the electrodeposition, and was determined using ICP-OES.

Nitrogen adsorption was performed at 77K on Quantachrome autosorb iQ to calculate Brunauer-Emmett-Teller (BET) surface area and pore volumes of bare carbon sheets, gold-coated carbon sheets, and gold-coated carbon sheets functionalized with 4-acetamidothiophenol. Surface area was calculated from the nitrogen isotherm curves ranging from 0.1 to 0.3 of relative pressure. Carbon Sheet based samples were cut into small pieces and were activated prior to measurement by heating the sample at 175° C. for 12 h under vacuum. Adsorption point at approximately P/P₀=0.99 was used to determine the total pore volume of each material. The micropore volume was determined using NL-DFT kernels for N₂ in cylindrical pores on carbon.

High-magnification imagery of the gold on carbon was acquired using a JEOL 7001F Scanning Electron Microscope (SEM). Secondary electron (SE) and back-scattered electron (BE) images were obtained at an accelerating voltage of 10 keV, whereas qualitative compositional information was obtained using energy-dispersive x-ray analysis (EDS) and performed at an accelerating voltage of 20 keV.

Additional and/or alternative conductors can comprise various substrates and/or coatings on the substrates. Examples of conductor substrates can include, but are not limited to, graphite, graphene, carbon nanotubes, carbon sheets, carbon black, copper, aluminum, silver, gold, platinum, iron, steel, brass, or combinations thereof. The conductor substrates can be coated with gold, silver, platinum, aluminum, copper, graphene, carbon sheets, carbon nanotubes, carbon black, or combinations thereof. In certain embodiments, the coatings can be a bonding layer and can enhance binding of a polarizable sorbent molecule to the substrate. As described elsewhere herein, the conductors can further comprise a catalyst. Examples of catalyst can include, but are not limited to, mixed metal oxides, spinels, perovskites, iron oxides in alumina, platinum-rhodium, Mo—Co, and similar bimetallic alloys, nickel and nickel-containing catalysts, silver or gold on alumina, NiO—TiO₂/WO₃, TiCl₃ on MgCl₂, or combinations thereof.

Thiol titration was used to determine the uptake of a polarizable molecule by the Au-coated porous carbon substrates. The absorption measurements were performed on an Agilent Cary 60 UV-Vis spectrophotometer. A pre-weighed sample of an Au/C substrate was immersed in a solution of the chromophore in ethanol of known concentration (target 1 mM) for 24 hours. The uptake of the chromophore was determined by the change of the absorption of the chromophore before and after the substrate immersion. To ensure the accuracy of the absorption measurements by bringing the chromophore solution absorption to the range of ˜0.3-1.0 a.u., the solutions used for the substrate functionalization were diluted 50 times for the absorption analysis.

The sorption enthalpy changes during the hydrofluorocarbon (HFC, R-32 or difluoromethane) sorption and desorption on the chromophore-functionalized electrode when the capacitor is switched on and off was measured using calorimetry. calorimetric measurements were performed using a Setaram C-80 Calvet type calorimeter. Stainless steel cells (internal volume 7.5 cm³) equipped with a dosing valve were used for measuring the heat of adsorption and desorption of the HFC in the presence of the chromophore and applied potential. The capacitor was fabricated as described below to fit inside the stainless-steel cells. The sorption enthalpy was measuring during the HFC sorption and desorption on the chromophore-functionalized electrode when the capacitor is switched on and off under isothermal conditions at 298 K and 45 psig of HFC.

Quantification of the HFC exchange upon switching the capacitor on and off was done in a custom-built pressure cell equipped with gas exchange and electrical connections. The rectangular cavity of the cell contained the capacitor consisting of a porous carbon sheet glued to a steel plate (working electrode), a second steel plate (counter-electrode), both separated by a layer of a porous ceramic dielectric. Three identical capacitors (identical materials, dimensions, and plate separation) were constructed and tested. The only difference among these capacitors was the treatment of the carbon (working) electrode. The first (control) capacitor had a bare porous carbon as the working electrode. The second (control) capacitor had a gold-coating porous carbon as the working electrode. The third capacitor was nearly identical to the second capacitor but hosted the chromophore (4-acetamidothiophenol) inside the pores via covalent bond between the gold surface and the thiol functionality of the chromophore. The cell was coupled to a Residual Gas Analyzer (RGA) to determine the HFC mass exchange via mass spectrometry.

The nitrogen isotherm plots obtained from nitrogen adsorption/desorption measurements on carbon sheets before and after gold electrocoating both exhibited type II behavior. The H₂-type hysteresis in the nitrogen adsorption/desorption is attributed to presence of narrow mouths (ink-bottle type pores). During adsorption nitrogen occupies all pores completely, but during desorption, the nitrogen needs to pass through the narrow pore's mouth, which occurs at relatively lower pressure than the actual pressure leading to hysteresis. Both carbon sheet and carbon sheet after gold electroplating showed large uptakes of nitrogen at low pressures (P/P₀<0.1) which clearly indicates the presence of pores available for nitrogen sorption. From BET calculated measurements, the surface area of bare carbon sheet was 535 m²/g with a pore average volume of 0.49 cm³/g, the surface area decreased to 350 m²/g (pore volume of 0.30 cm³/g) when a carbon substrate was coated with gold for 1 hour using a 2 mA/cm² current density. The amount of gold deposited under these conditions was 10.2% by weight, as measured by ICP-MS. The functionalization of the gold-coated carbon sheet with chromophore 4-acetamidothiophenol further reduced the surface area to 316 m²/g and the pore volume to 0.21 cm³/g. The hysteresis in nitrogen isotherm completely disappeared after the functionalization, clearly indicating that the pores are coated with chromophore. The results for all the preparation stages of the porous conductive electrode are presented in Table 1.

TABLE 1
BET surface area and pore volume measurements for the
porous carbon substrate before and after gold electroplating
followed by the chromophore functionalization

| Material | Surface area, m²/g | Pore volume, cm³/g |
|---|---|---|
| Carbon Sheet | 524.8 | 0.4868 |
| Carbon Sheet After Gold | 338.8 | 0.3028 |
| Electroplating | | |
| Carbon Sheet After Gold | 316.0 | 0.2067 |
| Electroplating followed by | | |
| chromophore functionalization | | |

In addition to the pore volume and surface area changes, the Au/carbon functionalization by the chromophore was characterized by thiol titration. It was determined that the 4-acetamidothiophenol uptake by the Au/carbon substrate was 13% by weight.

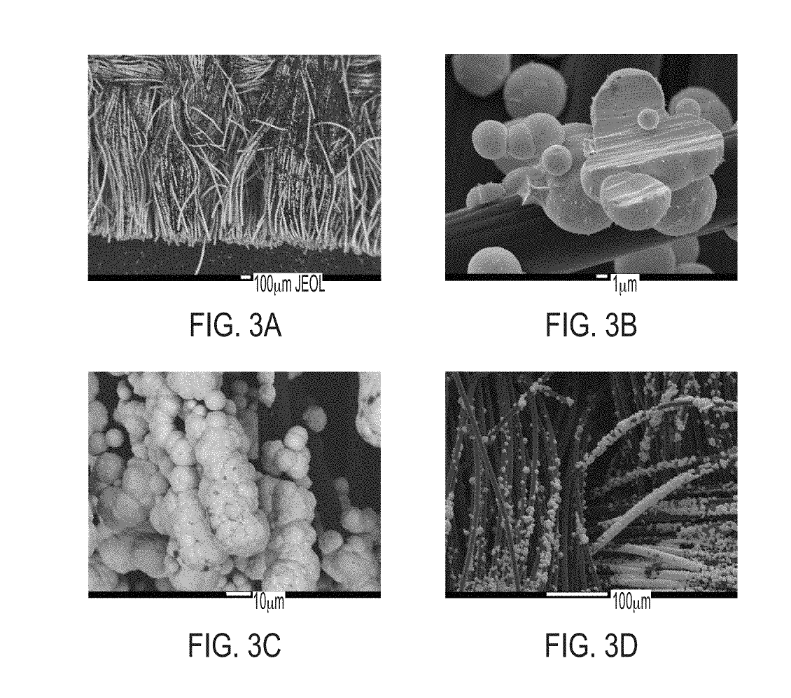

The Au coverage was imaged by SEM (FIG. 3). The distribution of Au on the carbon mat is characterized by clumps of spheres and hemispheres adhered to the surface of individual carbon fibers. As the general coverage is discontinuous over the entire mat, some areas are sparsely covered by globules, whereas other groups of fibers are entirely sheathed in Au, especially near the cut ends of the C mat. In the interior of the C fabric, Au is present, however, no fibers where partially coated as observed on the cut ends.

The occurrence of the Au-coated ends of the fibers may be attributed to more exposed surface area and better penetration of the solution into the C fabric. The discontinuous pattern of Au deposition on the surface of the fabric is more likely a product of the Au-coating process.

Ideal compressors are isentropic thermodynamic systems (having zero net change in system entropy on cycling), and the energy input required is a function of the change in enthalpy of the fluid, its latent heat of vaporization, which is 4.5 kcal mol⁻¹ for difluoromethane. In the solid-state-molecular pumping embodiments described herein, it is expected that this value would be higher due to the additional enthalpy change associated with adsorption and desorption of refrigerant by the chromophore (hydrogen bonding breaking and formation) during the polarization sorption cycle. According to the open literature, the enthalpy of hydrogen bonding between an HFC refrigerant CHF₂(CF₂)₅CF₃ and the strong base triethylamine is 5 kcal/mol, suggesting that the expected enthalpy change values upon adsorption and desorption of refrigerant in the capacitor would be in the order of 9-10 Kcal/mol. Calorimetry analysis was carried out on an (non-porous) operating capacitor to quantify enthalpy changes upon adsorption-desorption of difluoromethane molecules at the capacitor.

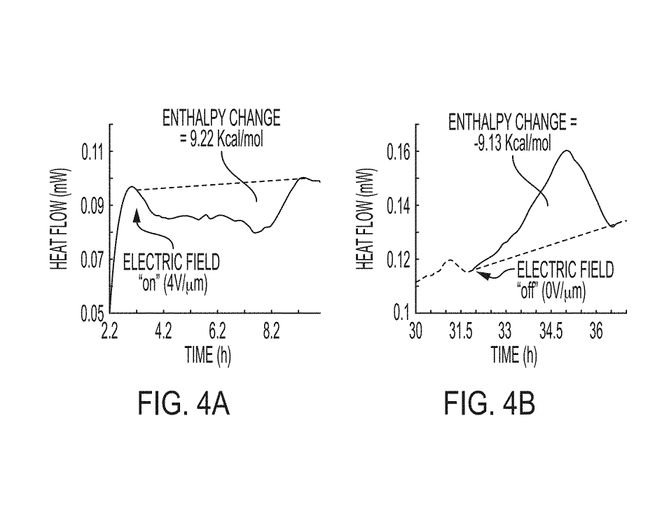

Calorimetric measurements showed that a chromophore-coated capacitor does exhibit an enthalpy change in presence of a refrigerant gas, whereas no such effects were observed in the control experiments without the presence of both the chromophore and refrigerant. Four experiments were performed including three control experiments where a capacitor was subjected to an applied electric field (“on” position) followed by switching the electric field “off”. The heat of adsorption and desorption was measured on four different capacitors as follow; 1) bare capacitor in the presence of nitrogen, 2) bare capacitor in the presence of refrigerant, 3) chromophore-functionalized capacitor (one electrode) in the presence of nitrogen, and 4) chromophore-functionalized capacitor (one electrode) in the presence of refrigerant. Only did the chromophore-functionalized capacitor in the presence of refrigerant show a reversible enthalpy change upon switching “on” and “off” the applied electric field. FIG. 4 also shows that the values for enthalpy change were in the range predicted verifying the hypothesis that, in addition to the latent heat of vaporization, H-bonding interactions between the chromophore and the refrigerant molecules are taking place upon polarizing the chromophore (“on” position).

We estimated an enthalpy change of −9.2 Kcal/mol for the capacitor when the capacitor was switched “on” (refrigerant adsorption) and 9.13 Kcal/mol when in the “off” position (refrigerant desorption). The similar absolute enthalpy changes for adsorption and desorption suggest that these interactions are reversible in nature where upon switching “on” the capacitor an exothermic process takes place involving H-bonding formation and refrigerant condensation while when switching “off” the capacitor an endothermic process occur with H-bonding breaking followed by vaporization of the refrigerant molecules.

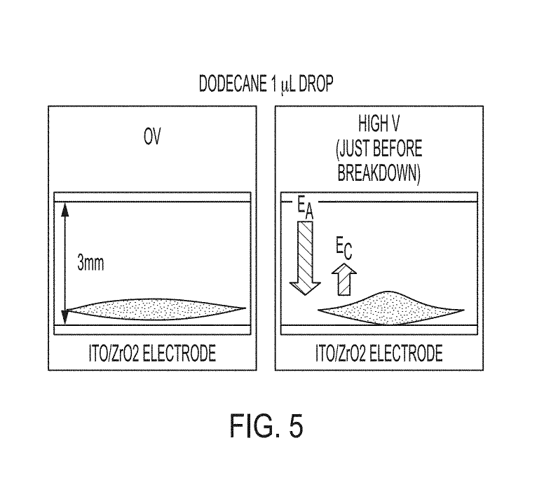

First, we checked the effect of the applied voltage on the polarization of chromophore on a surface of non-polar electrodes to determine the ability of the chromophore to influence the field of the dielectric breakdown. The application of an electric field to a double-layer capacitor where one of the electrodes is coated with the chromophore showed that a higher applied voltage is required for a breakdown of the capacitor dielectric as compared to the same capacitor without the chromophore coating. By measuring the dielectric break-down voltage of the capacitor with a 1 μL droplet of a model refrigerant liquid placed on the ITO/ZrO₂ or ITO/ZrO₂-chromophore functionalized electrode it was determined that the functionalization of ITO/ZrO₂ with the organic chromophore, an electric field of 2.1 V/μm was required to breakdown the dielectric as compared to 1.4 V/μm for a non-functionalized ITO/ZrO₂ (FIG. 5). The reason for this difference is the local electric field in the opposite direction of the applied external potential, generated by the active molecular coating (polarizable chromophore).

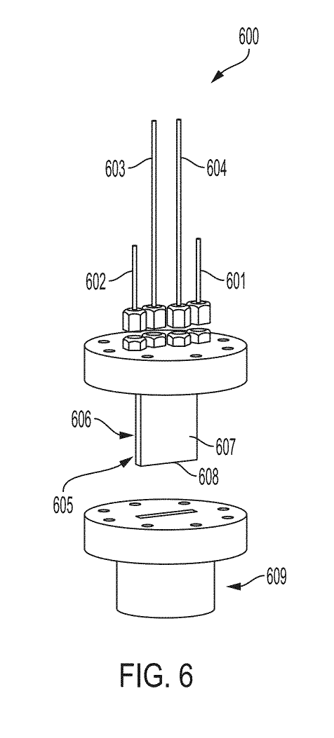

Next, in order to demonstrate the concept of the pumping action based on molecular polarization under applied bias, a capacitor cell 600 was fabricated. A schematic of the cell is shown in FIG. 6. The hermetically sealed cell 609 equipped with gas inlet 601 and outlet 602 and two electrical leads 603 and 604 contains the capacitor 605 built with a gold-coated carbon electrode 606 and steel electrode 607 separated by a porous ceramic dielectric 608. The gold-coated carbon sheet was also treated with a 4-acetamidothiophenol solution to functionalize the surface with the chromophore. Under the applied bias inside the capacitor, the chromophore layer was expected to be capable of reversibly bind the HFC due to the induced polarization. By simply switching “on” and “off” a capacitor. In the “on” position (compression cycle), polarizable molecules within the capacitor cavity can generate temporary dipoles in response to the applied electric field attracting and concentrating refrigerant molecules via hydrogen bonding. When the capacitor is switched off, the polarization disappears together with the H-bonding interaction, and the refrigerant molecules are set free (expansion cycle). Specifically to this capacitor-HFC system, the reversible sorption mechanism is hypothesized to consist of 1) polarization of the chromophore under an applied electric field, followed by 2) two hydrogen bonding interactions involving a) the oxygen of the amide functionality of the chromophore and the hydrogen atoms of the difluoromethane fragment, and b) the hydrogen bound to the nitrogen in the chromophore and the fluorine atoms of the HFC. When the capacitor is switched off, the polarization is removed, and the strength of the H-bonding is reduced setting the HFC molecules free. This simple concept provides a physical basis for non-mechanical pumping. The electrode material and construction had a large surface area to provide sufficient number of binding sites for the HFC to attach to the electrode due to the polarization of the chromophore. According to the surface area analysis, the surface area decreased as a result of the gold deposition onto the carbon (Table 1) and subsequent functionalization of the surface by the chromophore. However, there was still enough pore volume for HFC to flow though.

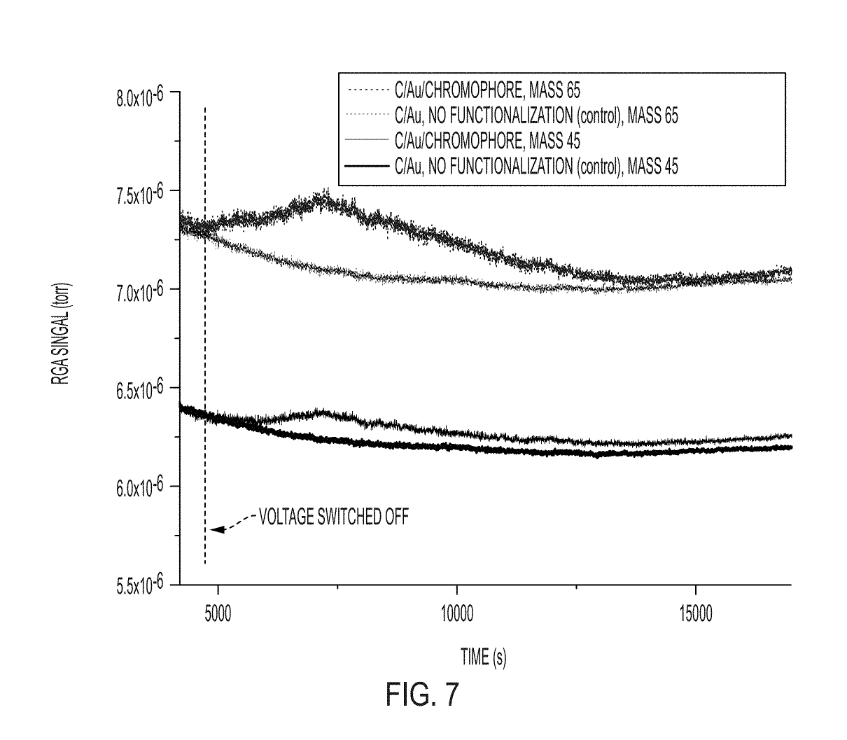

The sorption-desorption of the HFC refrigerant during cycling (i.e., turning on and off) the voltage to the capacitor was monitored using an RGA mass spectrometer connected to the capacitor cell. To test the polarization-induced sorption-desorption principle, the capacitor cell was pressurized with 9 psi of HFC followed by application of 1.5 KV (E˜3 V/μm) to the cell electrodes while under pressure for 1 hour. Once the voltage has switched off, the depolarized electrode can no longer retain the refrigerant, which will desorb and exit the cell. The RGA traces for the two HFC mass fragments (masses 45 and 65) after the removal of the polarizing voltage are shown in FIG. 7. This Figure demonstrates HFC adsorption/desorption cycling in the same fashion as a mechanical or thermal pump. The main difference is the fact that this molecular pumping concept does not require moving parts and can, in principle, be used to pump any fluid against pressure gradients significantly more efficiently.

The rise of the signals of the HFC coming off the C/Au electrode functionalized with 4-acetamidothiophenol corresponds to the refrigerant release when the capacitor voltage is switched off. Similarly, when the capacitor is switched on, produce a decrease in the HFC mass signal due to the adsorption/concentration of HFC inside the capacitor. Such HFC adsorption/desorption cycling is not observed in the base line experiments where the electrode contained no chromophore. The fact that both 45 and 65 masses respond in sync rules out the possibility that species other than the HFC are responsible for the desorption signal.

For the application of this concept in automotive compressors, the following rationale should be considered. The amount of active material (chromophore) required will depend on the cycling frequency, the pumping rate (0.23-0.52 mol s⁻¹ for the benchmark system), and the volumetric capacity for refrigerant of the material. The volumetric capacity for CO₂-saturated porous materials can be as high as 7 mol L⁻¹ at 1 bar and room temperature. A polarization sorption device with a volumetric capacity of 1 mol L⁻¹ cycling at 1 Hz would then require 0.2-0.5 L of chromophore to achieve the target pumping rates. These conservative estimates suggest that the device volume, is reasonable for a “drop-in” replacement for the benchmark compressor.

Using a pre-determined calibration curve of the supplied HFC pressure and the RGA response, we estimated the amount of the HFC released (exchanged) as a result of the electrode depolarization to be on the order of 3*10⁻⁵ g/cm² of the electrode. Based on the mass of chromophore in the porous electrode, this value signifies an HFC mass exchange capacity of 0.11 mol HFC/L of chromophore. If it is considered that the surface area of the capacitor was only 300 m²/g and that porous materials such as zeolite-templated porous carbon with surface areas in the order of 3,300 m²/g are available, the above required refrigerant capacities could be achieved for a drop-in replacement of a mechanical compressor.

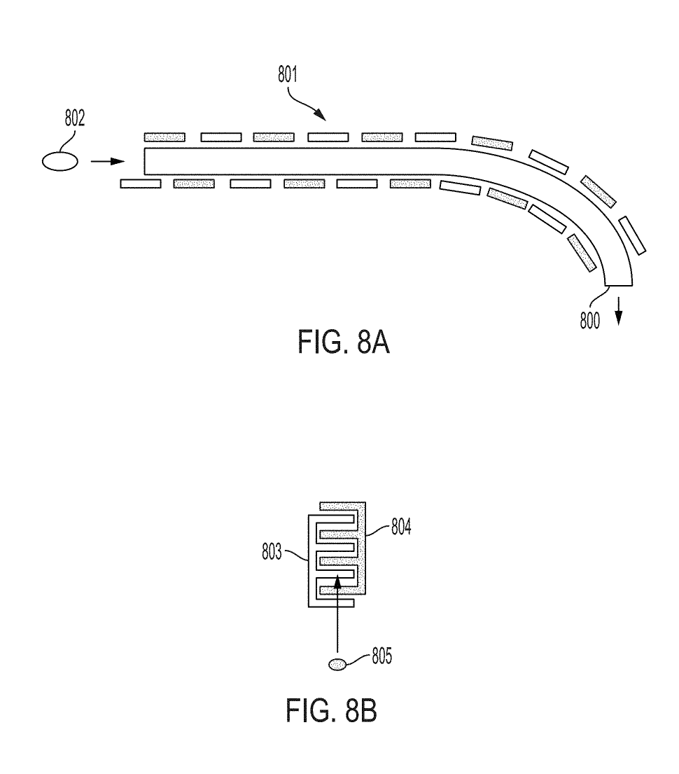

Referring to FIGS. 8A and 8B, schematic illustrations depict embodiments in which the POSSM pump further comprises a plurality of pairs of electrically connected electrodes. As shown in FIG. 8A, the plurality of pairs of electrically connected electrodes 801 (a pair denoted as a light and dark electrode) can be arranged along a sorbate-propagation path 800 to cause flow of the sorbate 802. Alternatively, as shown in FIG. 8B, the plurality of pairs of electrically connected electrodes 803 and 804 can be arranged in an interleaved or interdigitated configuration to cause flow of the sorbate 805. The pairs of electrodes can be selectively switched between the first and second conditions in a coordinated manner, thereby causing flow of the sorbate molecules.

In view of the many possible embodiments to which the principles of the disclosed invention may be applied, it should be recognized that the illustrated embodiments included herein and in the attachments are only preferred examples of the invention and should not be taken as limiting the scope of the invention. Rather, the scope of the invention is defined by the following claims. We therefore claim as our invention all that comes within the scope and spirit of these claims.

What is claimed is:

1. A method comprising the steps of:
alternating a polarization-switched, solid-state, molecular (POSSM) pump between a first condition and a second condition, the POSSM pump comprising a pair of electrically connected electrodes, at least one of which has surfaces on which polarizable molecules are attached, or having between the electrodes a dielectric material with the polarizable molecules attached thereto, or having both, wherein in the first condition a non-zero electric potential difference is applied between the conductors and in the second condition, a lower electric potential difference is applied relative to the first condition; and
Adsorbing sorbate molecules from a fluid to the polarizable molecules in the first or second condition and desorbing the sorbate molecules from the polarizable molecules in the second or first condition, respectively.

2. The method of claim 1, wherein the polarizable molecules comprise non-centrosymmetric molecules.

3. The method of claim 1, wherein the polarizable molecules comprise 4-acetamidothiophenols, quinoxalines, pyridines, pyrimidines, pyrrole, tetracyanoquinodimethane, donor substituted tetracyanoquinodimethanes, quinones, thiophenes, benzothiophenes, or combinations thereof.

4. The method of claim 1, further comprising alternating the sorbate molecule's polarization state in the first and second conditions.

5. The method of claim 1, wherein the sorbate molecule comprises a refrigerant molecule.

6. The method of claim 1, wherein the sorbate molecules are not charged molecules or particles.

7. The method of claim 1, further comprising reversibly changing an adsorption enthalpy value of the polarizable molecule in the presence of the sorbate molecule when switching between the first and second conditions.

8. The method of claim 1, wherein the sorbate comprises a liquid, a gas, or combination of both.

9. The method of claim 1, wherein the dielectric material comprises a porous material.

10. The method of claim 1, wherein said adsorbing sorbate molecules further comprises forming hydrogen bonds between the sorbate molecules and the polarizable molecules.

11. The method of claim 1, wherein the dielectric material, one or more of the electrodes, or a combination thereof comprises a catalyst material the further comprising the step of catalyzing a reaction involving the sorbate via the catalyst material.

12. The method of claim 1, wherein the POSSM pump further comprises a plurality of pairs of electrically connected electrodes.

13. The method of claim 12, wherein the plurality of pairs of electrically connected electrodes is arranged along a sorbate-propagation path and further comprising the step of selectively switching the pairs of electrodes between the first and second conditions in a coordinated manner, thereby causing flow of the sorbate molecules.

14. A composition, comprising:
A sorbent material attached to surfaces of a conductor, attached to surfaces of a dielectric material adjacent to the conductor, or attached to both, the sorbent material comprising polarizable molecules, wherein the polarizable molecules change polarization state in response to an applied electric field and wherein an adsorption affinity of the polarizable molecules for a sorbate also changes in response to the electric field.

15. The composition of claim 14, wherein the polarizable molecules comprise 4-acetamidothiophenols, quinoxalines, pyridines, pyrimidines, pyrrole, tetracyanoquinodimethane, donor substituted tetracyanoquinodimethanes, quinones, thiophenes, benzothiophenes, or combinations thereof.

16. The composition of claim 14, wherein the sorbate comprises refrigerant compounds.

17. The composition of claim 14, wherein an adsorption-desorption enthalpy changes of the polarizable molecules and the sorbate molecules have a non-zero value.

18. The composition of claim 14, wherein the conductor, the dieletric material, or both comprise a catalyst that catalyzes reactions involving the sorbate.

19. The composition of claim 14, wherein the sorbate molecules are not charged molecules or particles.

20. The composition of claim 14, wherein the sorbate molecules comprise polarizable molecules, hydrogen bond donors, hydrogen bond acceptors, charged molecules, polar molecules, or a combination thereof.
